(19) United States
(12) Patent Application Publication
(10) Pub. No.: US 2025/0279755 A1
(43) Pub. Date: Sep. 4, 2025

(54) DIFFERENTIAL POWER AMPLIFIERS WITH COUPLED BIASING

(71) Applicant: Skyworks Solutions, Inc., Irvine, CA (US)

(72) Inventors: Philip John Lehtola, Cedar Rapids, IA (US); Nathan Lucas Nuzum, Quasqueton, IA (US); Ajinkya Namdeorao More, Hiawatha, IA (US); Anuranjan Hosagavi Puttaraju, Aliso Viejo, CA (US)

(21) Appl. No.: 19/055,403

(22) Filed: Feb. 17, 2025

Related U.S. Application Data
(60) Provisional application No. 63/560,972, filed on Mar. 4, 2024.
(60) Provisional application No. 63/644,670, filed on May 9, 2024.

(51) Int. Cl. H03F 3/24; H04B 1/40

(52) U.S. Cl. CPC H03F 3/245; H04B 1/40; H03F 2200/451

(57) ABSTRACT

Apparatus and methods for biasing of differential power amplifiers are disclosed herein. In certain embodiments, a power amplifier includes a first gain transistor for amplifying a first signal component of a radio frequency (RF) signal and a second gain transistor for amplifying a second signal component of the RF signal. The power amplifier further includes a shared bias circuit for generating a bias signal for biasing an input of the first gain transistor and an input of the second gain transistor. The RF signal is coupled into the shared bias circuit to enhance biasing performance.

### CROSS-REFERENCE TO RELATED APPLICATIONS

This application claims the benefit of priority under 35 U.S.C. § 119 of U.S. Provisional Patent Application No. 63/644,670, filed May 9, 2024 and titled “DIFFERENTIAL POWER AMPLIFIERS WITH COUPLED BIASING,” and of U.S. Provisional Patent Application No. 63/560,972, filed Mar. 4, 2024 and titled “BIASING OF DIFFERENTIAL POWER AMPLIFIERS,” each of which is herein incorporated by reference in its entirety.

### BACKGROUND

### Field

Embodiments of the invention relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 410 MHz to about 7.125 GHz for Fifth Generation (5G) cellular communications in Frequency Range 1 (FR1) or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and/or wearable electronics.

### SUMMARY

In certain embodiments, the present disclosure relates to a mobile device. The mobile device includes a transceiver configured to generate a radio frequency input signal, and a front-end system including a power amplifier that includes a first amplification device configured to amplify a first signal component of a radio frequency input signal, a second amplification device configured to amplify a second signal component of the radio frequency input signal, a shared bias circuit having a first output configured to generate a first bias signal and a second output configured to generate a second bias signal, a first coupling impedance connected between the first output of the shared bias circuit and an input of the first amplification device, and a second coupling impedance connected between the second output of the shared bias circuit and an input of the second amplification device. The first coupling impedance is configured to provide the first bias signal to the input of the first amplification device and to couple the first signal component into the first output, and the second coupling impedance is configured to provide the second bias signal to the input of the second amplification device and to couple the second signal component into the second output.

In various embodiments, the power amplifier further includes an input terminal configured to receive the radio frequency input signal. According to a number of embodiments, the power amplifier further includes an input balun having a primary winding connected to the input terminal, and a secondary winding connect between the input of the first amplification device and the input of the second amplification device. In accordance with several embodiments, the power amplifier further includes a first capacitor connected between a first end of the secondary winding of the input balun and the input of the first amplification device, and a second capacitor connected between a second end of the secondary winding of the input balun and the input of the second amplification device.

In some embodiments, the shared bias circuit generates the first bias signal and the second bias signal based on a common reference signal.

In various embodiments, the first coupling impedance includes a first resistor and a first capacitor connected in parallel between the first output of the shared bias circuit and the input of the first amplification device, and the second coupling impedance includes a second resistor and a second capacitor connected in parallel between the second output of the shared bias circuit and the input of the second amplification device.

In several embodiments, the shared bias circuit includes a first emitter follower bipolar transistor having an emitter connected to the first output of the shared bias circuit, and a second emitter follower bipolar transistor having an emitter connected to the second output of the shared bias circuit. According to a number of embodiments, a base of the first emitter follower bipolar transistor and a base of the second emitter follower bipolar transistor receive a common reference signal.

In some embodiments, the first amplification device includes a first bipolar transistor having a base corresponding to the input of the first amplification device, and the second amplification device includes a second bipolar transistor having a base corresponding to the input of the second amplification device.

In various embodiments, the front end system includes a Doherty power amplifier system including the power amplifier. According to several embodiments, the power amplifier is one of a peaking amplifier or a carrier amplifier of the Doherty power amplifier system.

In certain embodiments, the present disclosure relates to a power amplifier. The power amplifier includes a first amplification device configured to amplify a first signal component of a radio frequency input signal, a second amplification device configured to amplify a second signal component of the radio frequency input signal, a shared bias circuit having a first output configured to generate a first bias signal and a second output configured to generate a second bias signal, a first coupling impedance connected between the first output of the shared bias circuit and an input of the first amplification device, and a second coupling impedance connected between the second output of the shared bias circuit and an input of the second amplification device. The first coupling impedance is configured to provide the first bias signal to the input of the first amplification device and to couple the first signal component into the first output, and the second coupling impedance is configured to provide the second bias signal to the input of the second amplification device and to couple the second signal component into the second output.

In various embodiments, the power amplifier further includes an input terminal configured to receive the radio frequency input signal. According to a number of embodiments, the power amplifier further includes an input balun having a primary winding connected to the input terminal, and a secondary winding connect between the input of the first amplification device and the input of the second amplification device. In accordance with several embodiments, the power amplifier further includes a first capacitor connected between a first end of the secondary winding of the input balun and the input of the first amplification device, and a second capacitor connected between a second end of the secondary winding of the input balun and the input of the second amplification device.

In some embodiments, the shared bias circuit generates the first bias signal and the second bias signal based on a common reference signal.

In various embodiments, the first coupling impedance includes a first resistor and a first capacitor connected in parallel between the first output of the shared bias circuit and the input of the first amplification device, and the second coupling impedance includes a second resistor and a second capacitor connected in parallel between the second output of the shared bias circuit and the input of the second amplification device.

In several embodiments, the shared bias circuit includes a first emitter follower bipolar transistor having an emitter connected to the first output of the shared bias circuit, and a second emitter follower bipolar transistor having an emitter connected to the second output of the shared bias circuit. According to a number of embodiments, a base of the first emitter follower bipolar transistor and a base of the second emitter follower bipolar transistor receive a common reference signal.

In various embodiments, the first amplification device includes a first bipolar transistor having a base corresponding to the input of the first amplification device, and the second amplification device includes a second bipolar transistor having a base corresponding to the input of the second amplification device.

In certain embodiments, the present disclosure relates to a method of radio frequency signal amplification in a mobile device. The method includes amplifying a first signal component of a radio frequency input signal using a first amplification device of a power amplifier, amplifying a second signal component of the radio frequency input signal using a second amplification device of the power amplifier, generating a first bias signal at a first output of a shared bias circuit and a second bias signal at a second output of the shared bias circuit, using a first coupling impedance to provide the first bias signal to the input of the first amplification device and to couple the first signal component into the first output, and using a second coupling impedance to provide the second bias signal to the input of the second amplification device and to couple the second signal component into the second output.

In various embodiments, the power amplifier further includes an input terminal configured to receive the radio frequency input signal. According to a number of embodiments, the power amplifier further includes an input balun having a primary winding connected to the input terminal, and a secondary winding connect between the input of the first amplification device and the input of the second amplification device. In accordance with some embodiments, the power amplifier further includes a first capacitor connected between a first end of the secondary winding of the input balun and the input of the first amplification device, and a second capacitor connected between a second end of the secondary winding of the input balun and the input of the second amplification device.

In several embodiments, the shared bias circuit generates the first bias signal and the second bias signal based on a common reference signal.

In some embodiments, the first coupling impedance includes a first resistor and a first capacitor connected in parallel between the first output of the shared bias circuit and the input of the first amplification device, and the second coupling impedance includes a second resistor and a second capacitor connected in parallel between the second output of the shared bias circuit and the input of the second amplification device.

In several embodiments, the shared bias circuit includes a first emitter follower bipolar transistor having an emitter connected to the first output of the shared bias circuit, and a second emitter follower bipolar transistor having an emitter connected to the second output of the shared bias circuit. According to a number of embodiments, a base of the first emitter follower bipolar transistor and a base of the second emitter follower bipolar transistor receive a common reference signal.

In various embodiments, the first amplification device includes a first bipolar transistor having a base corresponding to the input of the first amplification device, and the second amplification device includes a second bipolar transistor having a base corresponding to the input of the second amplification device.

In certain embodiments, the present disclosure relates to a power amplifier. The power amplifier includes an input terminal configured to receive a radio frequency input signal, a first amplification device configured to amplify a first signal component of the radio frequency input signal, a second amplification device configured to amplify a second signal component of the radio frequency input signal, and a shared bias circuit having an output configured to generate a bias signal for biasing an input of the first amplification device and an input of the second amplification device. The input terminal is coupled to the output of the shared bias circuit to compensate the bias signal for changes in power of the radio frequency input signal.

In some embodiments, the power amplifier further includes a coupling capacitor connected between the input terminal and the output of the shared bias circuit.

In several embodiments, the power amplifier further includes a first biasing impedance connected between the output of the shared bias circuit and the input of the first amplification device and a second biasing impedance connected between the output of the shared bias circuit and the input of the second amplification device.

In some embodiments, the power amplifier further includes an input balun having a primary winding connected to the input terminal, and a secondary winding connect between the input of the first amplification device and the input of the second amplification device. According to a number of embodiments, the power amplifier further includes a coupling capacitor connected between the input terminal and the output of the shared bias circuit. In accordance with several embodiments, the power amplifier further includes a biasing inductor connected between a center tap of the secondary winding and the output of the shared bias circuit. According to various embodiments, the power amplifier further includes a coupling inductor connected between a center tap of the secondary winding and the output of the shared bias circuit, the coupling inductor magnetically coupled to the input balun. In accordance with a number of the embodiments, the power amplifier further includes a first resistor and a first capacitor connected in parallel between a first end of the secondary winding of the input balun and the input of the first amplification device, and a second resistor and a second capacitor in parallel between a second end of the secondary winding of the input balun and the input of the second amplification device.

In some embodiments, the shared bias circuit includes an emitter follower bipolar transistor having an emitter connected to the output of the shared bias circuit.

In various embodiments, the first amplification device includes a first bipolar transistor having a base corresponding to the input of the first amplification device, and the second amplification device includes a second bipolar transistor having a base corresponding to the input of the second amplification device.

In certain embodiments, the present disclosure relates to a mobile device. The mobile device includes a transceiver configured to generate a radio frequency input signal, and a front-end system including a power amplifier that includes an input terminal configured to receive the radio frequency input signal, a first amplification device configured to amplify a first signal component of the radio frequency input signal, a second amplification device configured to amplify a second signal component of the radio frequency input signal, and a shared bias circuit having an output configured to generate a bias signal for biasing an input of the first amplification device and an input of the second amplification device. The input terminal is coupled to the output of the shared bias circuit to compensate the bias signal for changes in power of the radio frequency input signal.

In various embodiments, the power amplifier further includes a coupling capacitor connected between the input terminal and the output of the shared bias circuit.

In some embodiments, the power amplifier further includes a first biasing impedance connected between the output of the shared bias circuit and the input of the first amplification device and a second biasing impedance connected between the output of the shared bias circuit and the input of the second amplification device.

In several embodiments, the power amplifier further includes an input balun having a primary winding connected to the input terminal, and a secondary winding connect between the input of the first amplification device and the input of the second amplification device. According to a number of embodiments, the power amplifier further includes a coupling capacitor connected between the input terminal and the output of the shared bias circuit. In accordance with some embodiments, the power amplifier further includes a biasing inductor connected between a center tap of the secondary winding and the output of the shared bias circuit. According to various embodiments, the power amplifier further includes a coupling inductor connected between a center tap of the secondary winding and the output of the shared bias circuit, the coupling inductor magnetically coupled to the input balun. In accordance with a number of embodiments, the power amplifier further includes a first resistor and a first capacitor connected in parallel between a first end of the secondary winding of the input balun and the input of the first amplification device, and a second resistor and a second capacitor connected in parallel between a second end of the secondary winding of the input balun and the input of the second amplification device.

In some embodiments, the shared bias circuit includes an emitter follower bipolar transistor having an emitter connected to the output of the shared bias circuit.

In several embodiments, the front end system includes a Doherty power amplifier system including the power amplifier. According to a number of embodiments, the power amplifier is one of a peaking amplifier or a carrier amplifier of the Doherty power amplifier system.

In certain embodiments, the present disclosure relates to a method of radio frequency signal amplification in a mobile device. The method includes receiving a radio frequency input signal at an input terminal of a power amplifier, amplifying a first signal component of the radio frequency input signal using a first amplification device of the power amplifier, amplifying a second signal component of the radio frequency input signal using a second amplification device of the power amplifier, generating a bias signal for biasing an input of the first amplification device and an input of the second amplification device at an output of a shared bias circuit of the power amplifier, and compensating the bias signal for changes in power of the radio frequency input signal by providing coupling from the input terminal to the output of the shared bias circuit.

In some embodiments, the power amplifier further includes a coupling capacitor connected between the input terminal and the output of the shared bias circuit.

In several embodiments, the power amplifier further includes a first biasing impedance connected between the output of the shared bias circuit and the input of the first amplification device and a second biasing impedance connected between the output of the shared bias circuit and the input of the second amplification device.

In some embodiments, the power amplifier further includes an input balun having a primary winding connected to the input terminal, and a secondary winding connect between the input of the first amplification device and the input of the second amplification device. According to a number of embodiments, the power amplifier further includes a coupling capacitor connected between the input terminal and the output of the shared bias circuit. In accordance with several embodiments, the power amplifier further includes a biasing inductor connected between a center tap of the secondary winding and the output of the shared bias circuit. According to various embodiments, the power amplifier further includes a coupling inductor connected between a center tap of the secondary winding and the output of the shared bias circuit, the coupling inductor magnetically coupled to the input balun. In accordance with a number of embodiments, the power amplifier further includes a first resistor and a first capacitor connected in parallel between a first end of the secondary winding of the input balun and the input of the first amplification device, and a second resistor and a second capacitor connected in parallel between a second end of the secondary winding of the input balun and the input of the second amplification device.

In various embodiments, the shared bias circuit includes an emitter follower bipolar transistor having an emitter connected to the output of the shared bias circuit.

### BRIEF DESCRIPTION OF THE DRAWINGS

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4 is a schematic diagram of an example dual connectivity network topology.

FIG. 5A is a schematic diagram of a power amplifier according to one embodiment.

FIG. 5B is a schematic diagram of a power amplifier according to another embodiment.

FIG. 5C is a schematic diagram of a power amplifier according to another embodiment.

FIG. 6 is a schematic diagram of a power amplifier according to another embodiment.

FIG. 7 is a schematic diagram of a Doherty power amplifier system according to one embodiment.

FIG. 8A is a schematic diagram of a power amplifier according to another embodiment.

FIG. 8B is a schematic diagram of a power amplifier according to another embodiment.

FIG. 8C is a schematic diagram of a power amplifier according to another embodiment.

FIG. 9A is a schematic diagram of a power amplifier according to another embodiment.

FIG. 9B is a schematic diagram of a power amplifier according to another embodiment.

FIG. 10A depicts examples of graphs of voltage and distortion characteristics versus output power for one implementation of the power amplifier of FIG. 8A.

FIG. 10B depicts examples of graphs of voltage and distortion characteristics versus output power for one implementation of the power amplifier of FIG. 8B.

FIG. 10C depicts examples of graphs of voltage and distortion characteristics versus output power for one implementation of the power amplifier of FIG. 8C.

FIG. 11A depicts examples of graphs of voltage and distortion characteristics versus output power for one implementation of the power amplifier of FIG. 9A.

FIG. 11B depicts examples of graphs of voltage and distortion characteristics versus output power for one implementation of the power amplifier of FIG. 9B.

FIG. 12 is a schematic diagram of one embodiment of a mobile device.

FIG. 13 is a schematic diagram of a power amplifier system according to one embodiment.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15 and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

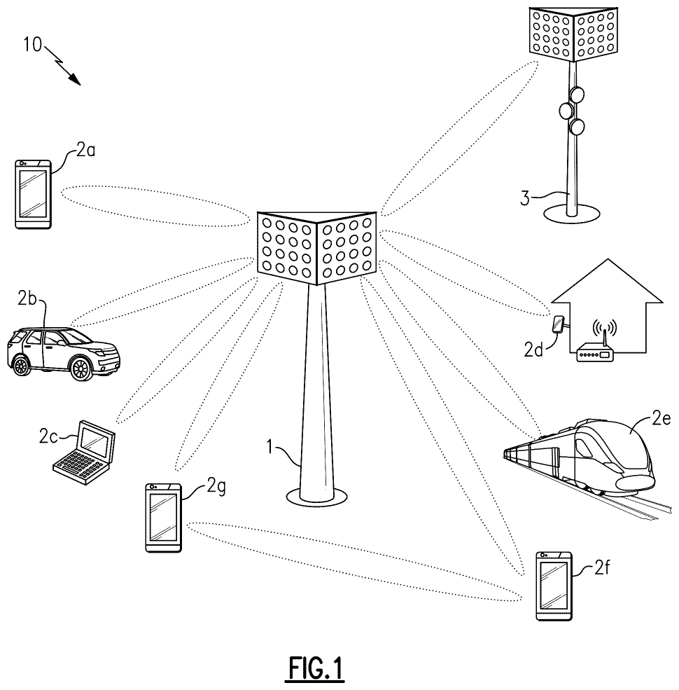

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as Wi-Fi®. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and Wi-Fi® technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed Wi-Fi® frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

In certain implementations, the communication network 10 supports supplementary uplink (SUL) and/or supplementary downlink (SDL). For example, when channel conditions are good, the communication network 10 can direct a particular UE to transmit using an original uplink frequency, while when channel condition is poor (for instance, below a certain criteria) the communication network 10 can direct the UE to transmit using a supplementary uplink frequency that is lower than the original uplink frequency. Since cell coverage increases with lower frequency, communication range and/or signal-to-noise ratio (SNR) can be increased using SUL. Likewise, SDL can be used to transmit using an original downlink frequency when channel conditions are good, and to transmit using a supplementary downlink frequency when channel conditions are poor.

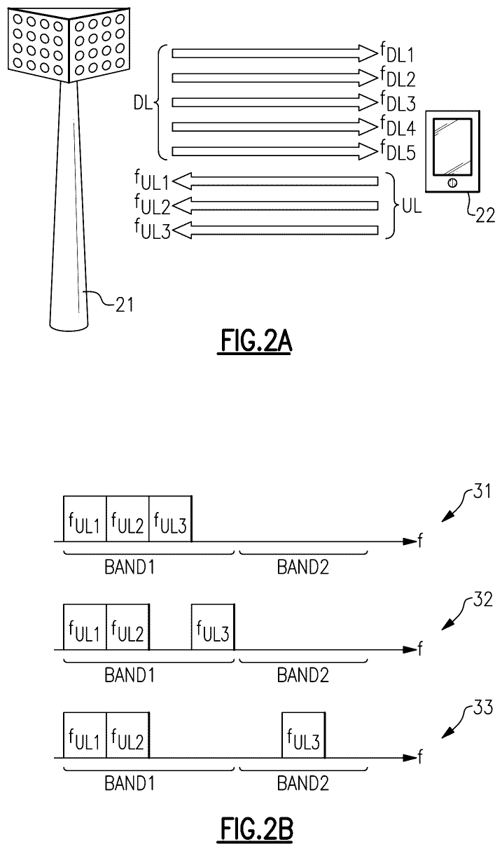

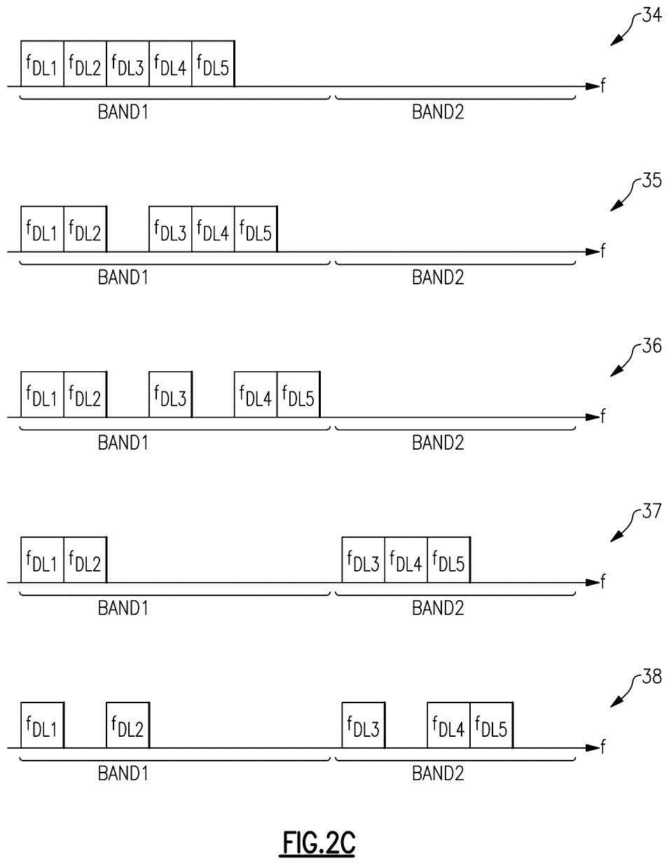

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as Wi-Fi®. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid Wi-Fi® users and/or to coexist with Wi-Fi® users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

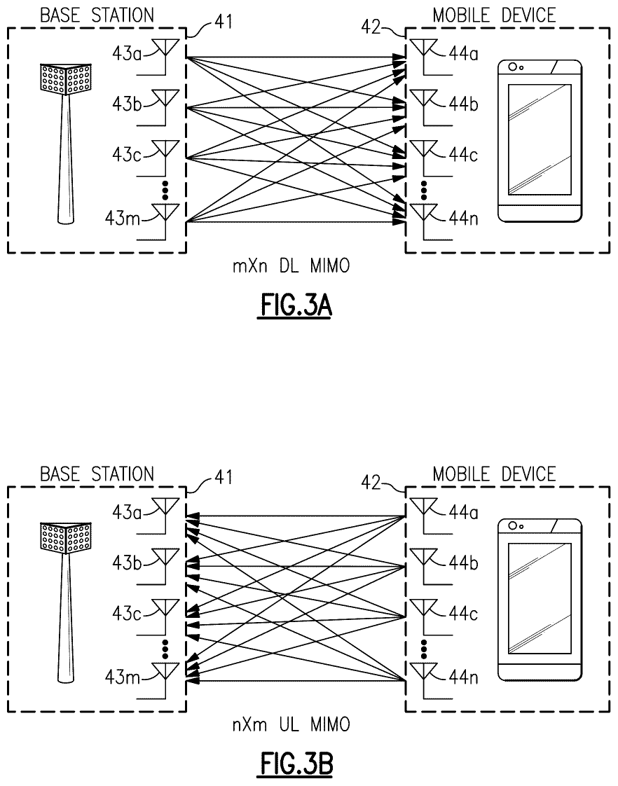

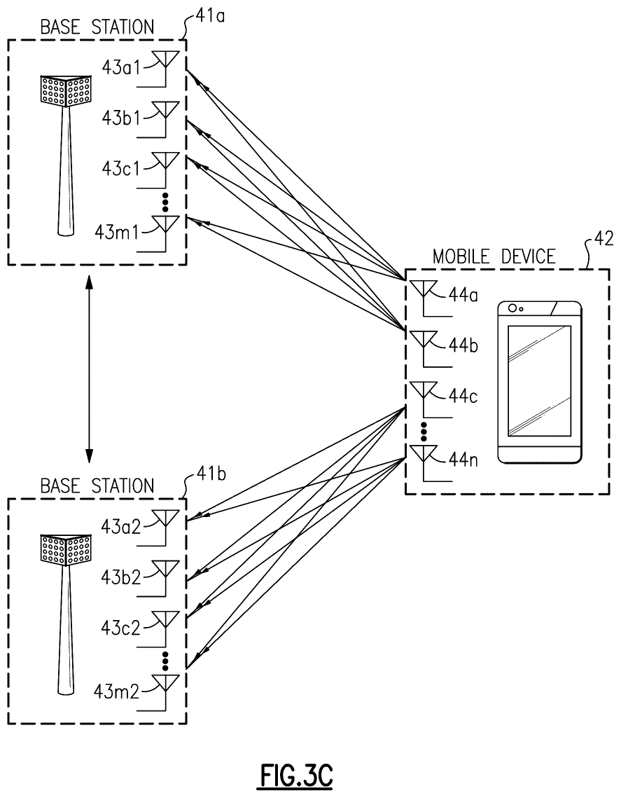

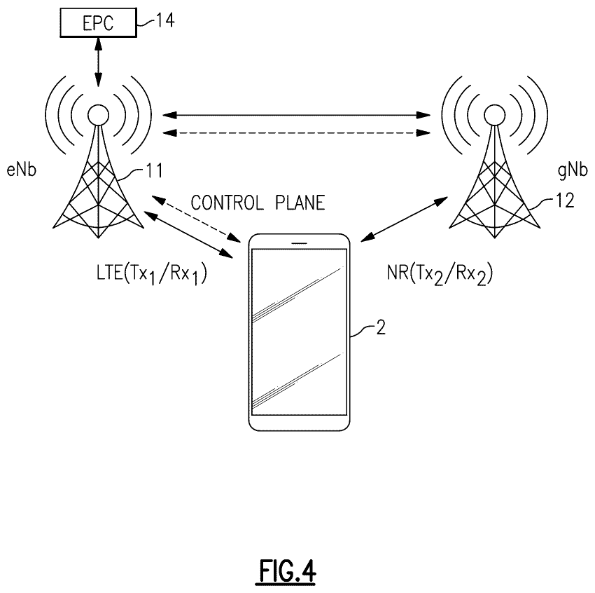

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

With the introduction of the 5G NR air interface standards, 3GPP has allowed for the simultaneous operation of 5G and 4G standards in order to facilitate the transition. This mode can be referred to as Non-Stand-Alone (NSA) operation or E-UTRAN New Radio-Dual Connectivity (EN-DC) and involves both 4G and 5G carriers being simultaneously transmitted from user equipment (UE).

In certain EN-DC applications, dual connectivity NSA involves overlaying 5G systems onto an existing 4G core network. For dual connectivity in such applications, the control and synchronization between the base station and the UE can be performed by the 4G network while the 5G network is a complementary radio access network tethered to the 4G anchor. The 4G anchor can connect to the existing 4G network with the overlay of 5G data/control.

FIG. 4 is a schematic diagram of an example dual connectivity network topology. This architecture can leverage LTE legacy coverage to ensure continuity of service delivery and the progressive rollout of 5G cells. A UE 2 can simultaneously transmit dual uplink LTE and NR carrier. The UE 2 can transmit an uplink LTE carrier Tx1 to the eNB 11 while transmitting an uplink NR carrier Tx2 to the gNB 12 to implement dual connectivity. Any suitable combination of uplink carriers Tx1, Tx2 and/or downlink carriers Rx1, Rx2 can be concurrently transmitted via wireless links in the example network topology of FIG. 1. The eNB 11 can provide a connection with a core network, such as an Evolved Packet Core (EPC) 14. The gNB 12 can communicate with the core network via the eNB 11. Control plane data can be wireless communicated between the UE 2 and eNB 11. The eNB 11 can also communicate control plane data with the gNB 12. Control plane data can propagate along the paths of the dashed lines in FIG. 4. The solid lines in FIG. 4 are for data plane paths.

In the example dual connectivity topology of FIG. 4, any suitable combinations of standardized bands and radio access technologies (e.g., FDD, TDD, SUL, SDL) can be wirelessly transmitted and received. This can present technical challenges related to having multiple separate radios and bands functioning in the UE 2. With a TDD LTE anchor point, network operation may be synchronous, in which case the operating modes can be constrained to Tx1/Tx2 and Rx1/Rx2, or asynchronous which can involve Tx1/Tx2, Tx1/Rx2, Rx1/Tx2, Rx1/Rx2. When the LTE anchor is a frequency division duplex (FDD) carrier, the TDD/FDD inter-band operation can involve simultaneous Tx1/Rx1/Tx2 and Tx1/Rx1/Rx2.

As discussed above, EN-DC can involve both 4G and 5G carriers being simultaneously transmitted from a UE. Transmitting both 4G and 5G carriers in a UE, such as a phone, typically involves two power amplifiers (PAs) being active at the same time. Traditionally, having two power amplifiers active simultaneously would involve the placement of one or more additional power amplifiers specifically suited for EN-DC operation. Additional board space and expense is incurred when designing to support such EN-DC/NSA operation.

### Examples of Features Supported by RFFE Systems Including Power Amplifiers

A radio frequency (RF) communication device can include multiple antennas for supporting wireless communications. Additionally, the RF communication device can include a radio frequency front-end (RFFE) system for processing signals received from and transmitted by the antennas. The RFFE system can provide a number of functions, including, but not limited to, signal filtering, signal partitioning and combining, controlling component connectivity to the antennas, and/or signal amplification.

RFFE systems can be used to handle RF signals of a wide variety of types, including, but not limited to, wireless local area network (WLAN) signals, Bluetooth® signals, and/or cellular signals. RFFE systems are also referred to herein as front-end systems.

RFFE systems can be used to process signals of a wide range of frequencies. For example, certain RFFE systems can operate using one or more low bands (for example, RF signal bands having a frequency content of 1 GHz or less, also referred to herein as LB), one or more mid bands (for example, RF signal bands having a frequency content between 1 GHz and 2.3 GHz, also referred to herein as MB), one or more high bands (for example, RF signal bands having a frequency content between 2.3 GHz and 3 GHz, also referred to herein as HB), and one or more ultrahigh bands (for example, RF signal bands having a frequency content between 3 GHz and 7.125 GHz, also referred to herein as UHB). In certain implementations, modules operate over mid band and high band frequencies (MHB).

Moreover, RFFE systems can also process millimeter wave frequency signals, such as those in FR2 of 5G.

RFFE systems can be used in a wide variety of RF communication devices, including, but not limited to, smartphones, base stations, laptops, handsets, wearable electronics, and/or tablets.

An RFFE system can be implemented to support a variety of features that enhance bandwidth and/or other performance characteristics of the RF communication device in which the RFFE system is incorporated.

For example, to support wider bandwidth, an increasing number of uplink carrier aggregation scenarios have been developed to support wider bandwidth. Additionally, the bandwidths for uplink and downlink cannot be arbitrarily sent since there is a minimum uplink bandwidth for maintaining a reliable link supported by the transport layer's ACK/NACK traffic. Thus, in 4G/5G, wideband uplink carrier aggregation should be supported to achieve higher bandwidth for downlink carrier aggregation.

Thus, an RFFE system can be implemented to support both uplink and downlink carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels, for instance up to five carriers. Carrier aggregation includes contiguous aggregation, in which contiguous carriers within the same operating frequency band are aggregated. Carrier aggregation can also be non-contiguous, and can include carriers separated in frequency within a common band or in different bands.

Transition from 4G to 5G is through non-standalone (NSA) operation, rather than directly to full standalone (SA) operation. Current networks operate in 4G and 5G concurrently by communicating with an eNodeB and a gNodeB simultaneously in an EN-DC mode of operation. Thus, 4G and 5G transmitters operate concurrently is such a phone.

To provide such feature support, an RFFE system can be implemented to support EN-DC.

Support for EN-DC can cover a wide range of frequency bands, including using a 4G band in the LB, MHB, HB, or UHB frequency ranges in combination with a 5G band in the LB, MHB, HB, or UHB frequency ranges. Thus, various combinations of EN-DC including, but not limited to, LB-LB EN-DC, MHB-MHB EN-DC, LB-MHB EN-DC, LB-UHB EN-DC, MHB-UHB EN-DC, and/or UHB-UHB EN-DC, are possible.

Moreover, in certain dual uplink transmission scenarios, it can be desirable to provide flexibility between swapping which antenna transmits a first RF transmit signal (for instance, one of a 4G signal or a 5G signal) on a first side of a phone board assembly and which antenna transmits a second RF transmit signal (for instance, the other of the 4G signal or the 5G signal) on a side of the phone board assembly. To provide such flexibility, an RFFE system can support a transmit swap function to selectively switch which antenna a particular RF transmit signal is transmitted from.

Another technique for increasing uplink capacity is uplink multiple-input multiple-output (MIMO) communications, in which multiple (for instance, two) power amplifiers transmit two different signals simultaneously on the same frequency using different antennas. MIMO communications benefit from higher signal to noise ratio, improved coding, and/or reduced signal interference due to spatial multiplexing differences of the radio environment. MIMO order refers to a number of separate data streams sent or received.

### Overview of Example Embodiments for Biasing of Differential Power Amplifiers

As wireless communication systems evolve more and more frequency bands are integrated into a single RF front-end module with a shared power amplifier used to provide amplification to RF signals associated with multiple frequency bands. For example, in certain applications only one power amplifier is employed.

Furthermore, constraints on power amplifier linearity and efficiency continue to tighten with evolving radio communications specifications. Thus, it is desirable for a power amplifier to have linear gain versus output power and linear phase versus output power characteristics. For example, it is desirable for power amplifiers to have little to no amplitude distortion (AM/AM) and phase distortion (AM/PM).

Differential power amplifier architectures like push-pull amplifiers, Doherty amplifiers, or a combination of both (Doherty push-pull) can be used for power amplification in multi-band and/or high-performance applications.

Achieving a linear gain and phase characteristic while maintaining output power and efficiency is a key challenge in power amplifier design.

A power amplifier's bias circuit (also referred to herein as a bias network) plays an important role in determining the power amplifier's gain and phase distortion characteristics. For example, high linearity can be achieved by keeping the bias voltage constant with changes in input power.

Apparatus and methods for biasing of differential power amplifiers are disclosed herein. In certain embodiments, a power amplifier includes a first gain transistor for amplifying a first signal component of an RF signal and a second gain transistor for amplifying a second signal component of the RF signal. The power amplifier further includes a shared bias circuit for generating a bias signal for biasing an input of the first gain transistor and an input of the second gain transistor. The RF signal is coupled into the shared bias circuit to enhance biasing performance.

For example, by injecting the RF signal into the shared bias network, the bias signals maintain the input voltages to the gain transistors more constant with increasing RF signal power.

Moreover, by using a shared bias circuit, the area of biasing circuitry is more compact and die area is saved. The area reduction in the bias network can help other blocks grow in area to improve power amplifier performance, such as power amplifier efficiency. Furthermore, in certain implementations the shared bias circuit uses one or more virtual grounds to help in shrinking area while maintaining amplitude and phase distortion benefits (for instance, achieving performance like that of using separate bias networks for each side of the differential power amplifier).

The teachings herein are applicable to a wide range of differential power amplifier architectures including, but not limited to, Doherty power amplifier systems, push-pull power amplifier systems, and Doherty push-pull power amplifier systems.

For example, a Doherty power amplifier includes a main or carrier amplifier and an auxiliary or peaking amplifier that operate in combination with one another to amplify an RF signal. The Doherty power amplifier combines a carrier signal from the carrier amplifier and a peaking signal from the peaking amplifier to generate an amplified RF output signal. In certain implementations, the carrier amplifier is enabled over a wide range of power levels by a class-AB bias circuit while the peaking amplifier is selectively enabled by a class-C bias circuit at high power levels. The class-AB bias circuit and/or the class-C bias circuit of a Doherty power amplifier can be implemented in accordance with one or more embodiments of the present disclosure.

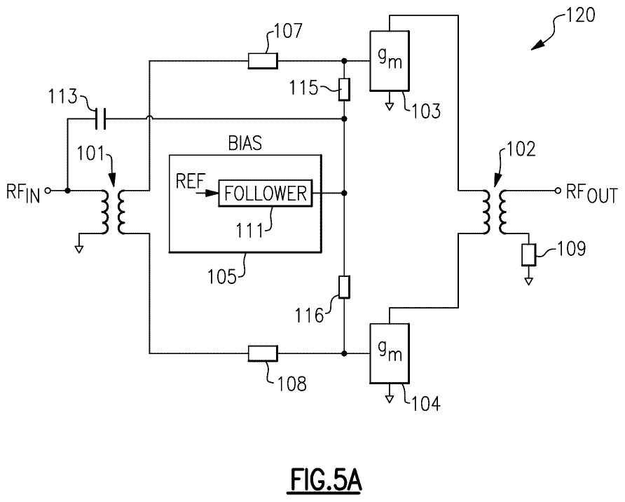

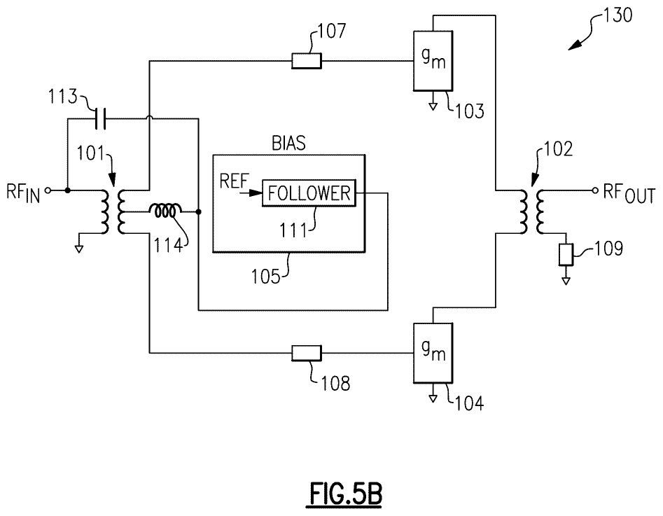

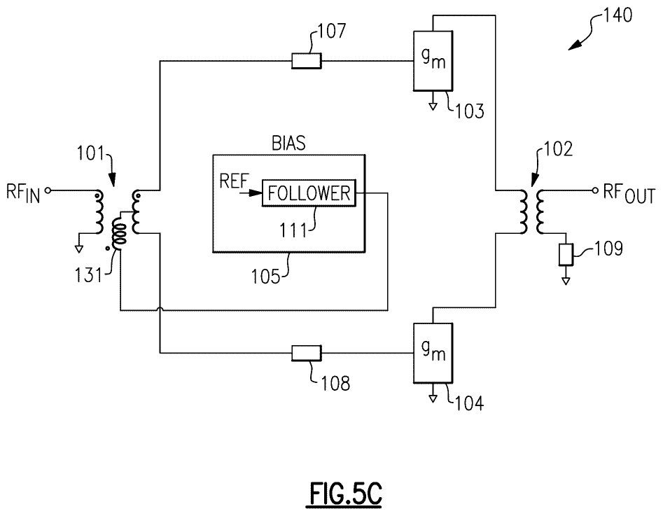

FIG. 5A is a schematic diagram of a power amplifier 120 according to one embodiment. The power amplifier 120 includes an input balun 101, an output balun 102, a first amplification (gₘ) device 103, a second amplification device 104, a bias circuit 105, a first input impedance 107, a second input impedance 108, an output termination impedance 109, a coupling capacitor 113, a first biasing impedance 115, and a second biasing impedance 116. The bias circuit 105 includes a follower device 111 that receives a reference signal REF.

In the illustrated embodiment, the input balun 101 includes a primary winding or side connected between an input terminal that receives an RF input signal RFIN and a ground voltage, and a secondary winding or side connected between a first end of the first input impedance 107 and a first end of the second input impedance 108. The primary winding of the input balun 101 receives the RF input signal as a single-ended signal, and the secondary winding outputs a differential RF input signal including a first RF signal component and a second RF signal component. In certain implementations, the first RF signal component corresponds to a non-inverted signal component and the second RF signal component corresponds to an inverted signal component having a phase difference of about 180° relative to the non-inverted signal component. Circuitry of a power amplifier that amplifies the first RF signal component is referred to herein as an A-side (or A), while circuitry of the power amplifier that amplifies the second RF signal component is referred to herein as a B-side (or B).

Although the power amplifier 120 of FIG. 5A includes the input balun 101 for converting the single-ended RF input signal to a differential RF input signal, other circuitry (for instance, an input splitting network or other suitable circuitry) can be used to separate a single-ended RF input signal into multiple signal components.

With continuing reference to FIG. 5A, the bias circuit 105 generates a bias signal at an output that also serves as a virtual ground to the differential configuration of the first amplification device 103 and the second amplification device 104. The first biasing impedance 115 includes a first end connected to the output of the bias circuit 105 and a second end connected to an input of the first amplification device 103. The input of the first amplification device 103 is also connected to a second end of the first input impedance 107. The second biasing impedance 116 includes a first end connected to the output of the bias circuit 105 and a second end connected to an input of the second amplification device 104. The input of the second amplification device 104 is also connected to a second end of the second input impedance 108.

In the illustrated embodiment, the bias circuit 105 includes a follower device 111 that receives a reference signal REF and that outputs the bias signal. The follower device 111 can include, for example, an emitter follower bipolar transistor or a source follower field-effect transistor (FET). Although the bias circuit 105 includes the follower device 111 in this embodiment, the teachings herein are applicable to other configurations of biasing circuitry.

The first amplification device 103 includes an output connected to first end of a primary winding of the output balun 102, and the second amplification device 104 includes an output connected to a second end of the primary winding of the output balun 102. The first amplification device 103 and the second amplification device 104 are also referenced to the ground voltage. The first amplification device 103 and the second amplification device 104 can be, for example, common emitter bipolar transistors or common source field-effect transistors.

With continuing reference to FIG. 5A, the output balun 102 further includes a secondary winding connected between an output terminal that provides an RF output signal RF_{OUT} and a first end of the output termination impedance 109. The second end of the output termination impedance 109 is connected to the ground voltage, in this example.

As shown in FIG. 5A, the coupling capacitor 113 is connected between the input terminal and the output of the bias circuit 105. The coupling capacitor 113 operates to couple the RF input signal RFIN into the output of the shared bias circuit 105 to enhance biasing performance. For example, by injecting the RF input signal RFIN into the shared bias circuit 105, the input voltages to the first amplification device 103 and the second amplification device 104 are maintained more constant with increasing RF signal power. Thus, compensation to inhibit input voltage droop at high RF signal power is provided.

Moreover, injecting the RF input signal RFIN into the shared bias circuit 105 provides the power amplifier 120 with superior amplitude distortion and phase distortion characteristics relative to an implementation in which the RF input signal RFIN is not coupled into the shared bias circuit 105.

FIG. 5B is a schematic diagram of a power amplifier 130 according to another embodiment. The power amplifier 130 includes an input balun 101, an output balun 102, a first amplification device 103, a second amplification device 104, a bias circuit 105, a first input impedance 107, a second input impedance 108, an output termination impedance 109, a coupling capacitor 113, and a biasing inductor 114.

The power amplifier 130 of FIG. 5B is similar to the power amplifier 120 of FIG. 5A, except that the power amplifier 130 of FIG. 5B omits the first biasing impedance 115 and the second biasing impedance 116 of FIG. 5A in favor of including the biasing inductor 114.

As shown in FIG. 5B, the biasing inductor 114 is connected between the output of the shared bias circuit 104 and a center tap of the secondary winding of the input balun 101. Thus, bias signals (for instance, bias currents) for both the first amplification device 103 and the second amplification device 104 are provided through the biasing inductor 114 to the inputs (for instance, bases or gates) of the amplification devices 103/104.

FIG. 5C is a schematic diagram of a power amplifier 140 according to another embodiment. The power amplifier 140 includes an input balun 101, an output balun 102, a first amplification device 103, a second amplification device 104, a bias circuit 105, a first input impedance 107, a second input impedance 108, an output termination impedance 109, and a coupled biasing inductor 131.

The power amplifier 140 of FIG. 5C is similar to the power amplifier 130 of FIG. 5B, except that the power amplifier 140 of FIG. 5C omits the coupling capacitor 113 and the biasing inductor 114 of FIG. 5B in favor of including the coupled biasing inductor 131.

In the illustrated embodiment, the coupled biasing inductor 131 is coupled (for instance, magnetically or electromagnetically) to the input balun 101 (for instance, to the primary winding of the input balun 101). The coupled biasing inductor 131 operates to couple the RF input signal RFIN into the output of the bias circuit 105. The coupled biasing inductor 131 is electrically connected between the center tap of the secondary winding of the input balun 101 and the output of the bias circuit 105, and serves to conduct bias signals (for instance, bias currents) provided from the bias circuit 105 to the inputs of the amplification devices 103/104.

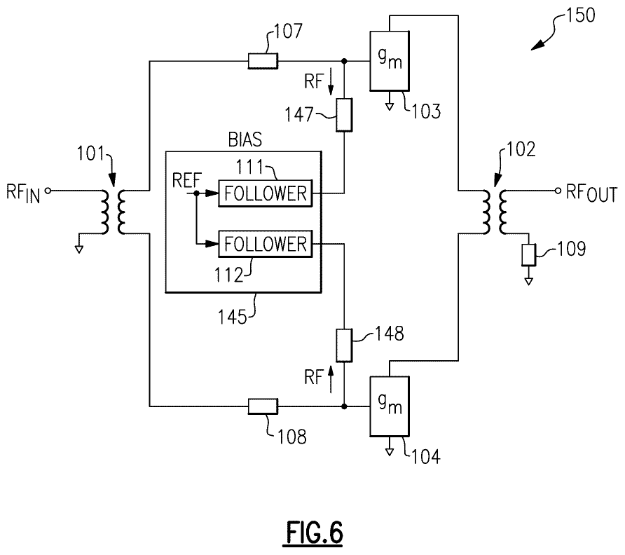

FIG. 6 is a schematic diagram of a power amplifier 150 according to another embodiment. The power amplifier 150 includes an input balun 101, an output balun 102, a first amplification device 103, a second amplification device 104, a bias circuit 145, a first input impedance 107, a second input impedance 108, an output termination impedance 109, a first coupling impedance 147, and a second coupling impedance 148. The bias circuit 145 includes a first follower device 111 and a second follower device 112 that receive a shared or common reference signal REF.

In the illustrated embodiment, the bias circuit 145 includes a first output that provides a first bias signal to an input of the first amplification device 103 through the first coupling impedance 147 and a second output that provides a second bias signal to an input of the second amplification device 104 through the second coupling impedance 148.

With continuing reference to FIG. 6, the first amplification device 103 amplifies a first RF signal component of the RF input signal RFIN while the second amplification device 104 amplifies a second RF signal component of the RF input signal RFIN. Additionally, the first coupling impedance 147 couples a portion of the first RF signal component into the first output of the bias circuit 145, while the second coupling impedance 148 couples a portion of the second RF signal component into the second output of the bias circuit 145.

Such RF signal coupling enhances biasing performance. For example, by injecting the RF signal components into the outputs of the shared bias circuit 145, the input voltages to the first amplification device 103 and the second amplification device 104 are maintained more constant with increasing RF signal power. Thus, compensation to inhibit input voltage droop at high RF signal power is provided.

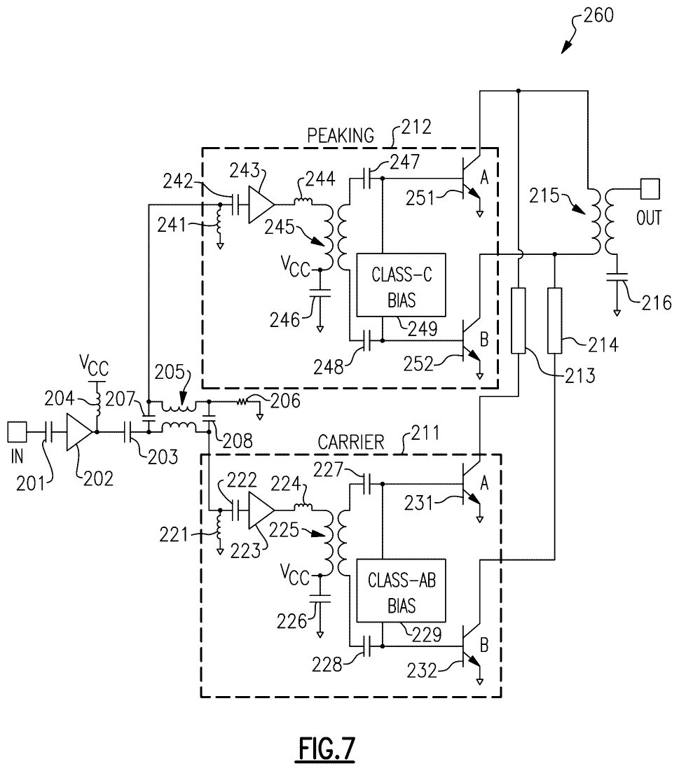

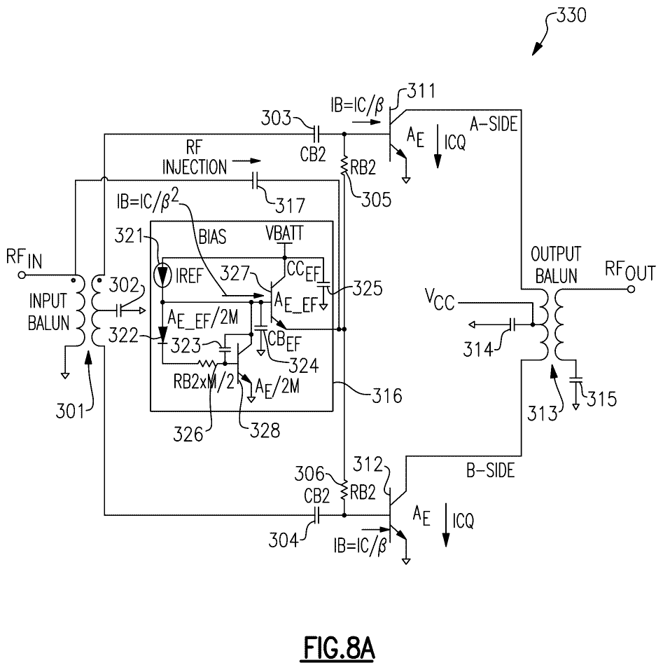

FIG. 7 is a schematic diagram of a Doherty power amplifier system 260 according to one embodiment. The Doherty power amplifier system 260 includes an input terminal IN, a first DC blocking capacitor 201, an input amplifier 202, a second DC blocking capacitor 203, an input bias inductor 204, an input balun 205, an input balun termination resistor 206, a first input balun capacitor 207, a second input balun capacitor 208, a carrier amplifier 211, a peaking amplifier 212, a first inverter impedance 213, a second inverter impedance 214, an output balun 215, an output termination capacitor 216, and an output terminal OUT.

The Doherty power amplifier system 260 depicts an example of a power amplifier system that can be implemented with biasing in accordance with one or more embodiments of the present disclosure. Although the Doherty power amplifier system 260 depicts an example of a power amplifier system that can benefit from the biasing schemes disclosed herein, the teachings herein are applicable to a wide range of power amplifier systems.

In the illustrated embodiment, the input amplifier 202 receives an RF input signal from the input terminal IN through the first DC blocking capacitor 201. An output of the input amplifier 202 receives a power amplifier supply voltage V_{CC} through the input bias inductor 204. Additionally, the output of the input amplifier 202 provides an amplified RF input signal to the input balun 205 through the second DC blocking capacitor 203.

The input balun 205 is connected with the depicted components to operate as an input signal separation circuit that separates the amplified RF input signal into a carrier input signal and a peaking input signal with a desired phase shift (for example, about ninety degrees in some implementations). In the illustrated embodiment, the input balun 205 includes a primary winding connected between the second DC blocking capacitor 203 and an input to the carrier amplifier 211, and a secondary winding connected between an input to the peaking amplifier 212 and a first end of the input balun termination resistor 206. The input balun termination resistor 206 further includes a second end electrically connected to ground. Additionally, the first input balun capacitor 207 and the second input balun capacitor 208 are each connected between the primary winding and the secondary winding at opposite ends of the input balun 205.

In the illustrated embodiment, the carrier amplifier 211 includes a first inductor 221, an input DC blocking capacitor 222, a carrier driver amplifier 223, a second inductor 224, a balun 225, a supply capacitor 226, a first input capacitor 227, a second input capacitor 228, a class-AB bias circuit 229, a first bipolar transistor 231, and a second bipolar transistor 232. The first inductor 221 is coupled between the input of the carrier amplifier 211 and ground. The carrier driver amplifier 223 receives the carrier input signal through the input DC blocking capacitor 222 and provides a single-ended carrier output signal to a first end of the primary winding of the balun 225 through the second inductor 224. The primary winding of the balun 225 further includes a second end coupled to the power amplifier supply voltage V_{CC} and to a first end of the supply capacitor 226. A second end of the supply capacitor 226 is electrically connected to ground. The secondary winding of the balun 225 includes a first end connected to the base of the first bipolar transistor 231 through the first input capacitor 227, and a second end connected to the base of the second bipolar transistor 232 through the second input capacitor 228. The emitter of the first bipolar transistor 231 is connected to ground while a collector of the first bipolar transistor 231 is connected to a first end of the first inverter impedance 213. The emitter of the second bipolar transistor 232 is connected to ground while a collector of the second bipolar transistor 232 is connected to a first end of the second inverter impedance 214.

With continuing reference to FIG. 7, the peaking amplifier 212 includes a first inductor 241, an input DC blocking capacitor 242, a peaking driver amplifier 243, a second inductor 244, a balun 245, a supply capacitor 246, a first input capacitor 247, a second input capacitor 248, a class-C bias circuit 249, a first bipolar transistor 251, and a second bipolar transistor 252. The first inductor 241 is coupled between the input of the peaking amplifier 212 and ground. The peaking driver amplifier 243 receives the peaking input signal through the input DC blocking capacitor 242 and provides a single-ended peaking output signal to a first end of the primary winding of the balun 245 through the second inductor 244. The primary winding of the balun 245 further includes a second end coupled to the power amplifier supply voltage V_{CC} and to a first end of the supply capacitor 246. A second end of the supply capacitor 246 is electrically connected to ground. The secondary winding of the balun 245 includes a first end connected to the base of the first bipolar transistor 251 through the first input capacitor 247, and a second end connected to the base of the second bipolar transistor 252 through the second input capacitor 248. The emitter of the first bipolar transistor 251 is connected to ground while a collector of the first bipolar transistor 251 is connected to a second end of the first inverter impedance 213. The emitter of the second bipolar transistor 252 is connected to ground while a collector of the second bipolar transistor 252 is connected to a second end of the second inverter impedance 214.

The output balun 215 includes a primary winding connected between the second end of the first inverter impedance 213 and the second end of the second inverter impedance 214. The output balun 215 further includes a secondary winding connected between the output terminal OUT and a first end of the output termination capacitor 216. The output termination capacitor 216 further includes a second end connected to ground.

The peaking amplifier 212 amplifies the peaking input signal and the carrier amplifier 211 amplifies the carrier input signal. The amplified RF peaking signal and the amplified RF carrier signal are combined using the impedance inverter to generate an RF output signal that is provided to the output terminal OUT.

As shown in FIG. 7, the peaking amplifier 212 includes the class-C bias circuit 249, which biases the bases of the peaking amplifier's bipolar transistors 251/252. Additionally, the carrier amplifier 212 includes the class-AB bias circuit 229, which biases the bases of the carrier amplifier's bipolar transistors 231/232. The class-C bias circuit 249 and/or the class-AB bias circuit 229 can be implemented in accordance with one or more embodiments of the present disclosure.

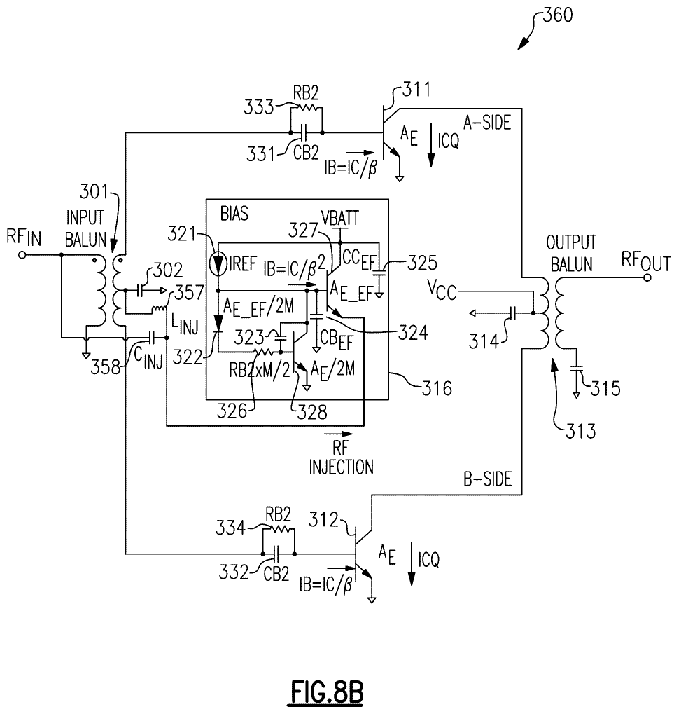

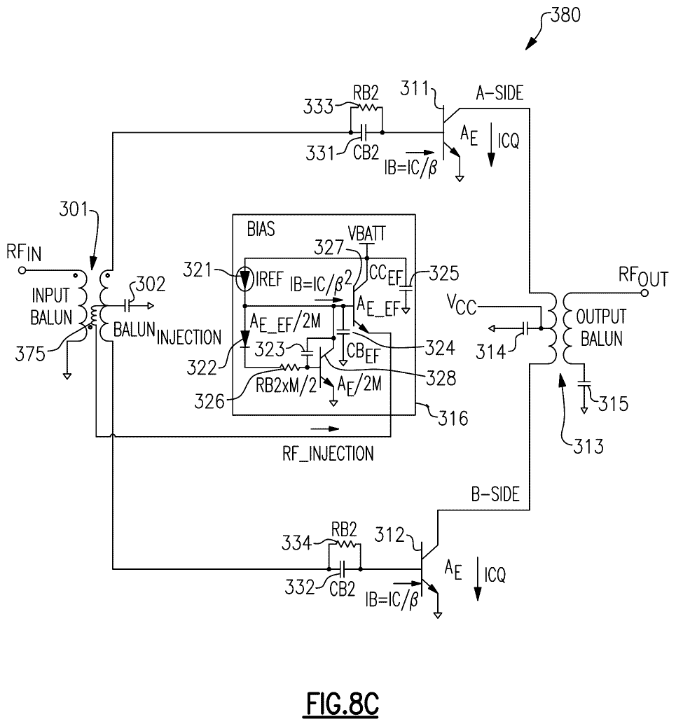

FIG. 8A is a schematic diagram of a power amplifier 330 according to another embodiment. The power amplifier 330 includes an input balun 301, an input center tap capacitor 302, a first input capacitor 303 (of capacitance CB2), a second input capacitor 304 (of capacitance CB2), a first biasing resistor 305 (of resistance RB2), a second biasing resistor 306 (of resistance RB2), a first bipolar transistor 311 (of area A_{E}), a second bipolar transistor 312 (of area A_{E}), an output balun 313, an output center tap capacitor 314, an output termination capacitor 315, a bias circuit 316, and a coupling capacitor 317.

The power amplifier 330 of FIG. 8A is similar to the power amplifier 120 of FIG. 5A, except that the power amplifier of FIG. 8A includes specific implementations of components and circuits as shown in the figure.

In the illustrated embodiment, the amplification devices are implemented as bipolar transistors 311/312 each connected in a common emitter configuration. The bipolar transistors 311/312 have a nominal collector current ICQ and a nominal base current IB=IC/β, wherein β is the nominal bipolar transistor gain. In certain implementations, the bipolar transistors 311/312 are implemented as heterojunction bipolar transistors (HBTs).

The bias circuit 316 includes a reference current source 321 (generating a reference current IREF), a diode 322 (with area A_{E_EF}/2M), a base-to-collector capacitor 323, a base capacitor 324 (of capacitance CB_{EF}), a collector capacitor 325 (of capacitance CC_{EF}), a resistor 326 (of resistance RB2×M/2), an emitter follower bipolar transistor 327 (of area A_{E_EF}), and a biasing bipolar transistor 328 (of area A_{E}/2M).

As shown in FIG. 8A, the base of the emitter follower bipolar transistor 327 receives a reference signal IB=IC/β² at a base and outputs a bias signal from the emitter. The collector of the emitter follower bipolar transistor 327 is connected to a battery voltage V_{BATT}. The bias signal is provided through the first biasing resistor 305 to the first bipolar transistor 311 and through the second biasing resistor 306 to the second bipolar transistor 312.

As shown in FIG. 8A, the RF input signal is coupled using the coupling capacitor 317 from the input terminal to the emitter of the emitter follower bipolar transistor 327. The injection from the input terminal to the bias improves both amplitude distortion (AM/AM) and phase distortion (AM/PM) by keeping the base voltages of the first and second bipolar transistors 311/312 relatively constant with increasing RF signal power.

FIG. 8B is a schematic diagram of a power amplifier 360 according to another embodiment. The power amplifier 360 includes an input balun 301, an input center tap capacitor 302, a first input capacitor 331 (of capacitance CB2), a second input capacitor 332 (of capacitance CB2), a first input resistor 333 (of resistance RB2), a second input resistor 334 (of resistance RB2), a first bipolar transistor 311, a second bipolar transistor 312, an output balun 313, an output center tap capacitor 314, an output termination capacitor 315, a bias circuit 316, a biasing inductor 357, and a coupling capacitor 358.

In comparison to the power amplifier 330 of FIG. 8A, the power amplifier 360 of FIG. 8B provides biasing from the output of the bias circuit 316 to the biasing inductor 357, which is coupled to a center tap of the secondary winding of the input balun 301. As shown in FIG. 8B, the parallel combination of the first input capacitor 331 and the first input resistor 333 is provided between a first end of the secondary winding of the input balun 301 and a base of the first bipolar transistor 311, while the parallel combination of the second input capacitor 332 and the second input resistor 334 is provided between a second end of the secondary winding of the input balun 301 and a base of the second bipolar transistor 312. Furthermore, the coupling capacitor 358 is included between the input terminal and the output of the bias circuit 316.

Thus, the depicted embodiment utilizes RF signal injection from the input terminal to the center tap feed of the input balun, while ballasting resistors 333/334 aid in keeping the base voltages of the first and second bipolar transistors 311/312 relatively constant with increasing RF signal power.

FIG. 8C is a schematic diagram of a power amplifier 380 according to another embodiment. The power amplifier 380 includes an input balun 301, an input center tap capacitor 302, a first input capacitor 331 (of capacitance CB2), a second input capacitor 332 (of capacitance CB2), a first input resistor 333 (of resistance RB2), a second input resistor 334 (of resistance RB2), a first bipolar transistor 311, a second bipolar transistor 312, an output balun 313, an output center tap capacitor 314, an output termination capacitor 315, a bias circuit 316, and a coupled biasing inductor 375.

The coupled biasing inductor 375 is coupled (for instance, magnetically or electromagnetically) to the input balun 301 (for instance, to the primary winding of the input balun 301). The coupled biasing inductor 375 operates to couple the RF input signal RF_{IN} into the output of the bias circuit 316. The coupled biasing inductor 375 is electrically connected between the center tap of the secondary winding of the input balun 301 and the output of the bias circuit 316, and serves to conduct bias signals provided from the bias circuit 316 to the inputs of the bipolar transistors 311/312.

The power amplifier of FIG. 8C is similar to the power amplifier 140 of FIG. 5C, except that the power amplifier of FIG. 8C includes specific implementations of components and circuits as shown in the figure.

In the illustrated embodiment, the amplification devices are implemented as bipolar transistors 311/312 each connected in a common emitter configuration. Additionally, the bias circuit 316 includes an emitter follower bipolar transistor 324. The coupling inductor 375 provides coupling from the input terminal of the power amplifier 380 to the emitter of the emitter follower bipolar transistor 327. The bias signal from the emitter follower bipolar transistor 327 flows through the coupling inductor 375. A parallel combination of a base capacitor 331/332 and a ballasting resistor 333/334 are included at the bases of the bipolar transistors 311/312, respectively.

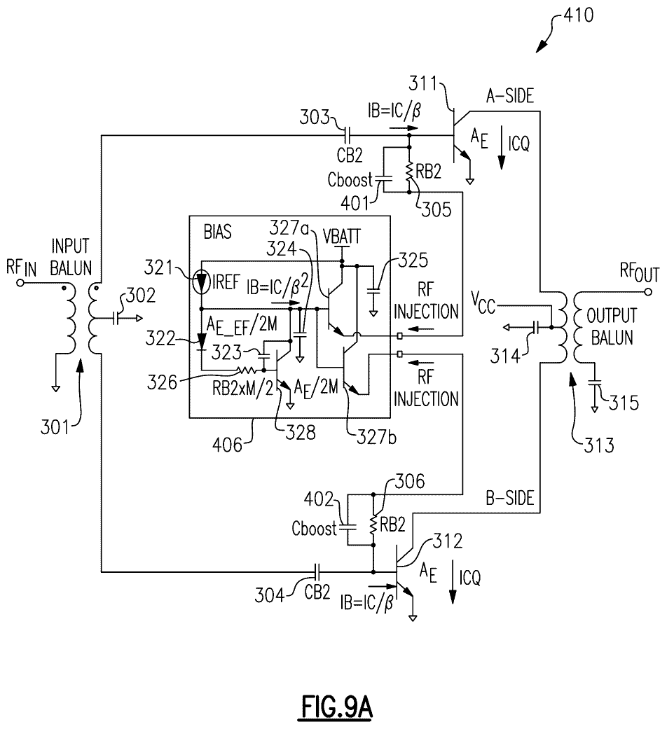

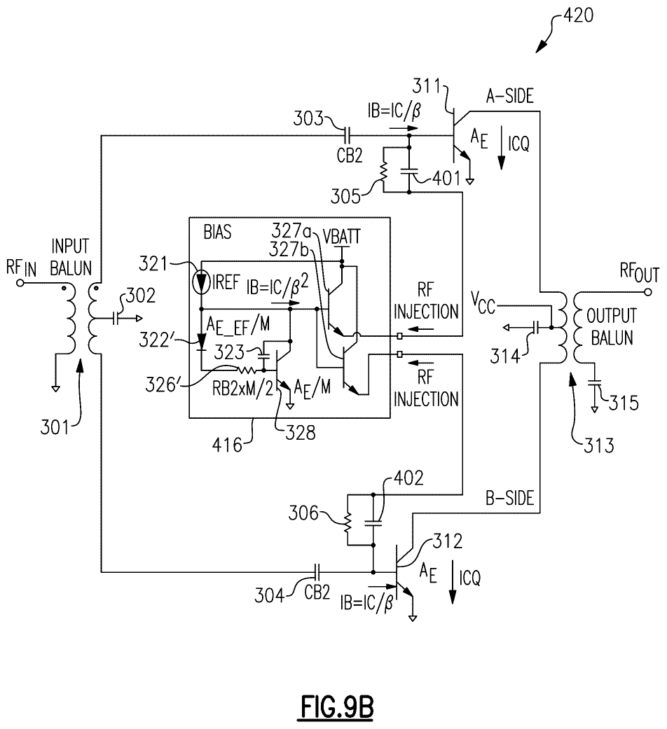

FIG. 9A is a schematic diagram of a power amplifier 410 according to another embodiment. The power amplifier 410 includes an input balun 301, an input center tap capacitor 302, a first input capacitor 303 (of capacitance CB2), a second input capacitor 304 (of capacitance CB2), a first biasing resistor 305 (of resistance RB2), a second biasing resistor 306 (of resistance RB2), a first bipolar transistor 311 (of area A_{E}), a second bipolar transistor 312 (of area A_{E}), an output balun 313, an output center tap capacitor 314, an output termination capacitor 315, a bias circuit 406, a first coupling capacitor 401, and a second coupling capacitor 402.

In comparison to the power amplifier 330 of FIG. 8A that uses the coupling capacitor 317 for RF signal injection, the power amplifier 410 of FIG. 9A includes the first coupling capacitor 401 and the second coupling capacitor 402, which are connected between a first output and a second output of the bias circuit 406, respectively, and the bases of the first bipolar transistor 311 and the second bipolar transistor 312.

In the illustrated embodiment, the bias circuit 406 includes a reference current source 321 (generating a reference current IREF), a diode 322 (with area A_{E_EF}/2M), a base-to-collector capacitor 323, a base capacitor 324, a collector capacitor 325, a resistor 326 (of resistance RB2×M/2), a first emitter follower bipolar transistor 327a, a second emitter follower bipolar transistor 327b, and a biasing bipolar transistor 328 (of area A_{E}/2M).

As shown in FIG. 9A, the bases of the emitter follower bipolar transistors 327a/327b receive a common reference signal IB=IC/β². The first emitter follower bipolar transistor 327a outputs a first bias signal from the emitter, and the second emitter follower bipolar transistor 327b outputs a second bias signal from the emitter.

Additionally, a parallel combination of the first boost capacitor 401 and the first biasing resistor 305 are included between the emitter of the first emitter follower bipolar transistor 327a and the base of the first bipolar transistor 311, and a parallel combination of a second boost capacitor 402 and a second biasing resistor 306 are included between the emitter of the second emitter follower bipolar transistor 327b and the base of the second bipolar transistor 312.

As shown in FIG. 9A, the first boost capacitor 401 provides RF signal injection of the first RF signal component amplified by the first bipolar transistor 311 into the emitter of the first emitter follower bipolar transistor 327a. Additionally, the second boost capacitor 402 provides RF signal injection of the second RF signal component amplified by the second bipolar transistor 312 into the emitter of the second emitter follower bipolar transistor 327b.

FIG. 9B is a schematic diagram of a power amplifier 420 according to another embodiment. The power amplifier 420 includes an input balun 301, an input center tap capacitor 302, a first input capacitor 303 (of capacitance CB2), a second input capacitor 304 (of capacitance CB2), a first biasing resistor 305 (of resistance RB2), a second biasing resistor 306 (of resistance RB2), a first bipolar transistor 311 (of area A_{E}), a second bipolar transistor 312 (of area A_{E}), an output balun 313, an output center tap capacitor 314, an output termination capacitor 315, a bias circuit 416, a first coupling capacitor 401, and a second coupling capacitor 402.

The power amplifier 420 of FIG. 9B is similar to the power amplifier 410 of FIG. 9A, except that the power amplifier 420 of FIG. 9B includes a different implementation of the bias circuit 416 that achieves smaller bias circuit area by scaling as well as removal of capacitors from the collectors and emitters of the emitter follower bipolar transistors.

For example, the bias circuit 416 includes a reference current source 321 (generating a reference current IREF), a diode 322′ (with area A_{E_EF}/M), a base-to-collector capacitor 323, a resistor 326 (of resistance RB2×M/2), a first emitter follower bipolar transistor 327a, a second emitter follower bipolar transistor 327b, and a biasing bipolar transistor 328 (of area A_{E}/M). The base capacitor 324 and the collector capacitor 325 of the bias circuit 406 of FIG. 9A are not included in the bias circuit 416 of FIG. 9B.

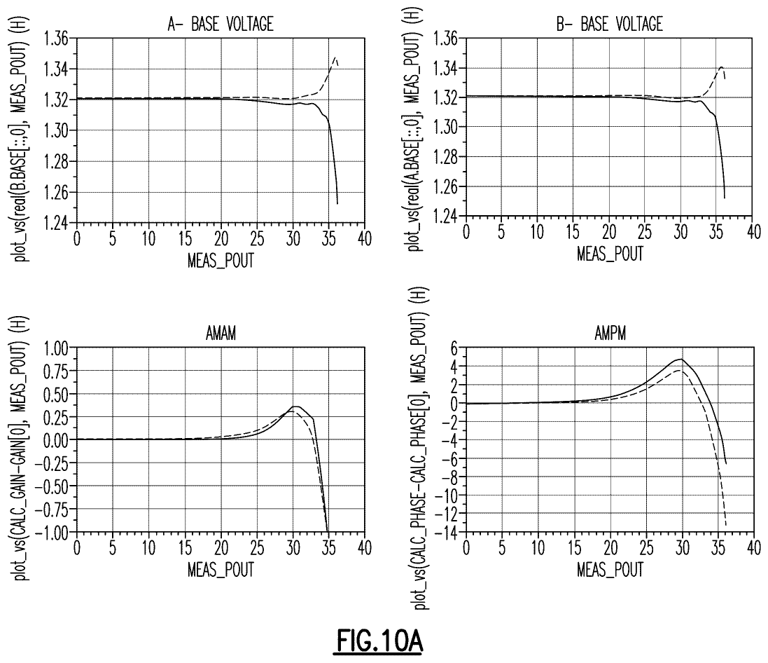

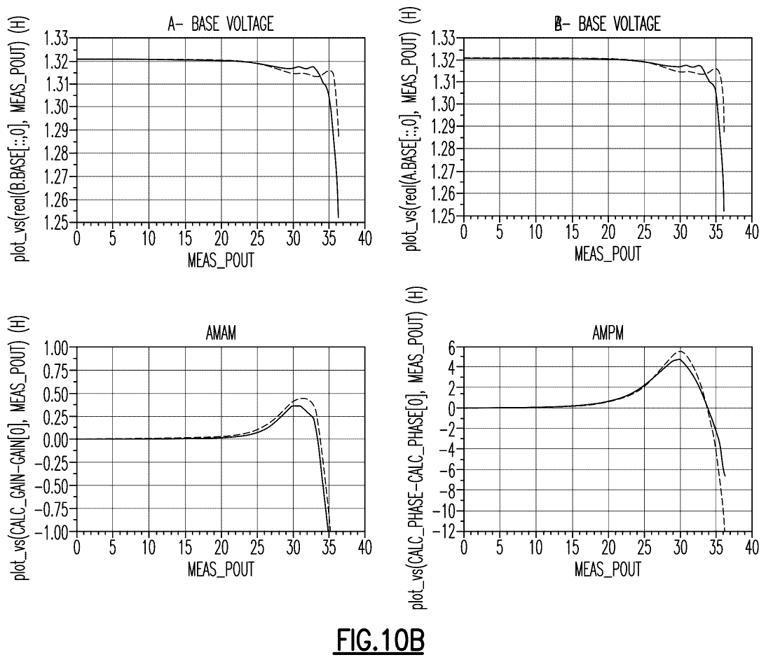

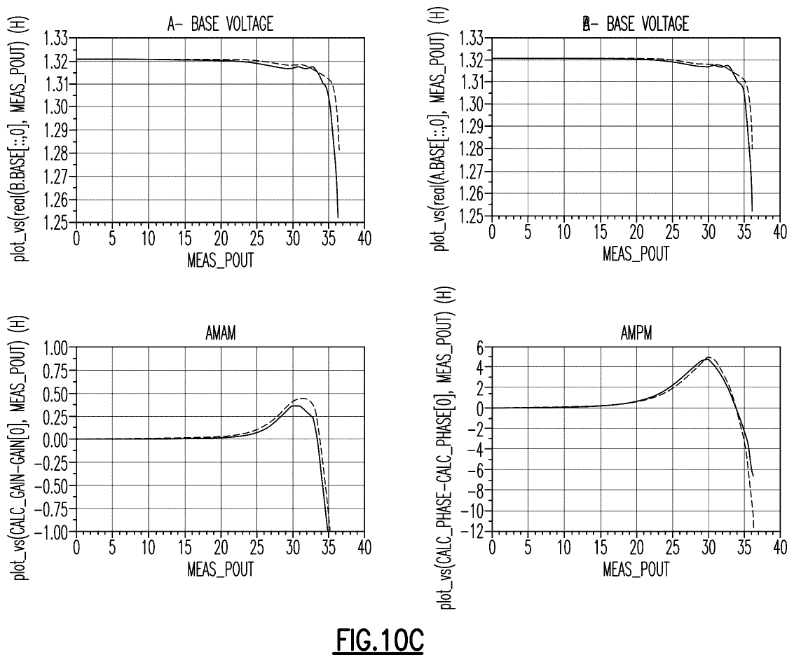

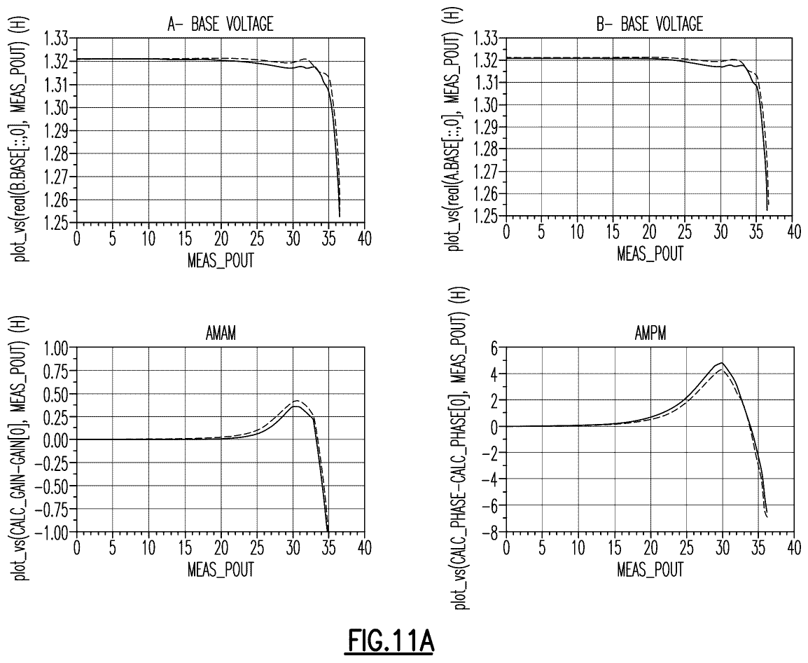

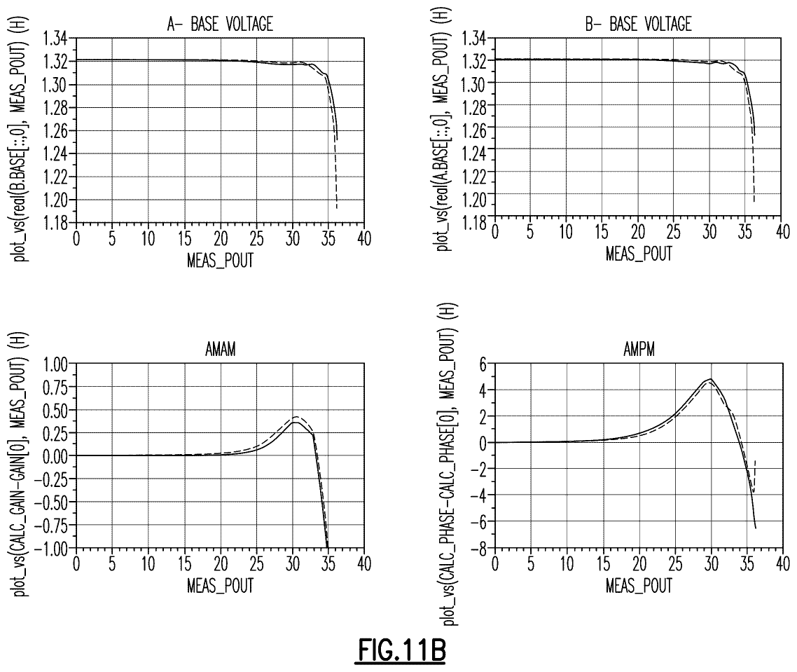

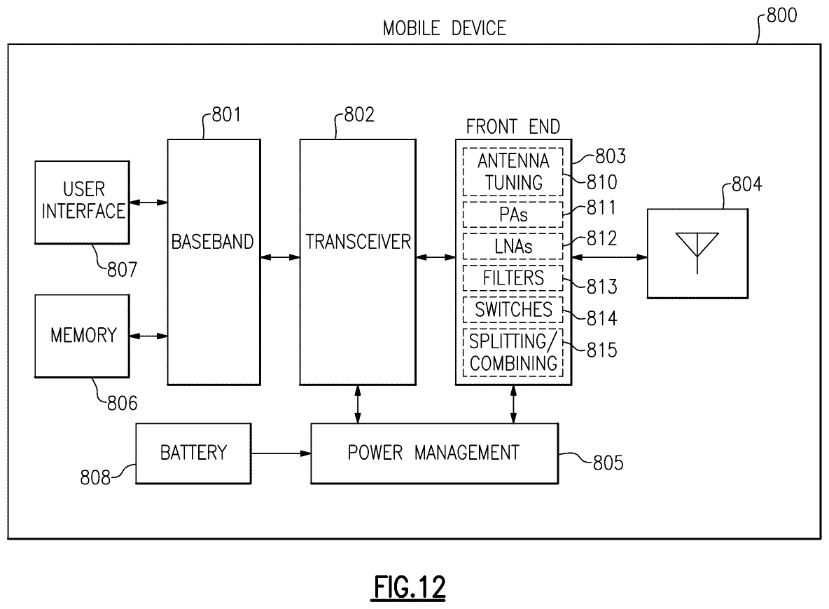

With general references to FIGS. 10A-11B, simulation results for various implementations of power amplifiers are shown. The graphs include plots in blue for a baseline case in which separate bias circuits are used for each side of the differential power amplifier. Using separate bias circuits results in a large die circuit area. The graphs include plots in red for results using a shared bias circuit for the indicated implementation scenario.

FIG. 10A depicts examples of graphs of voltage and distortion characteristics versus output power for one implementation of the power amplifier 330 of FIG. 8A.

FIG. 10B depicts examples of graphs of voltage and distortion characteristics versus output power for one implementation of the power amplifier 360 of FIG. 8B.

FIG. 10C depicts examples of graphs of voltage and distortion characteristics versus output power for one implementation of the power amplifier 380 of FIG. 8C.

FIG. 11A depicts examples of graphs of voltage and distortion characteristics versus output power for one implementation of the power amplifier 410 of FIG. 9A.

FIG. 11B depicts examples of graphs of voltage and distortion characteristics versus output power for one implementation of the power amplifier 420 of FIG. 9B.

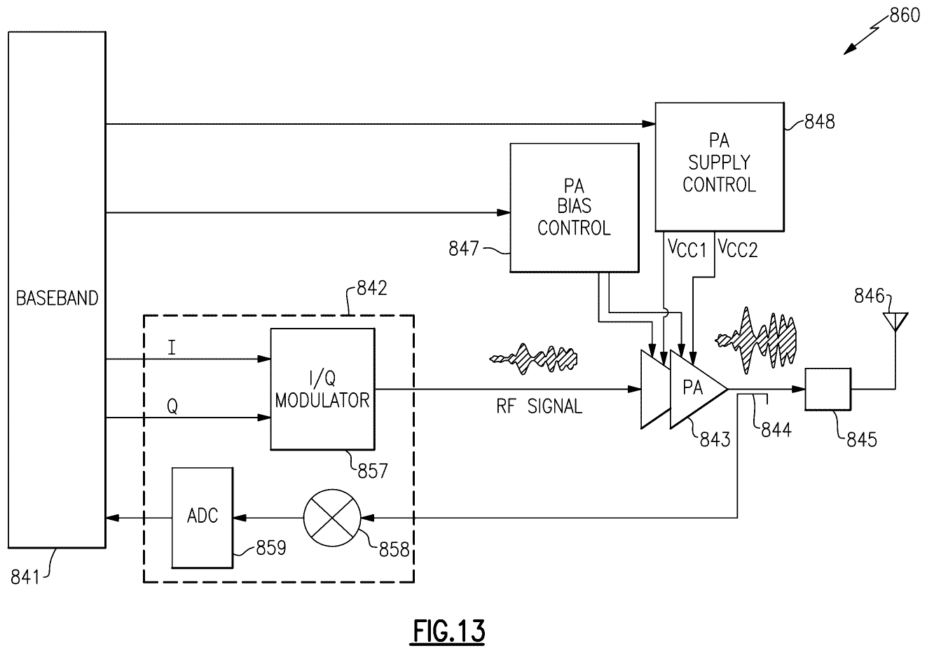

FIG. 12 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, Wi-Fi®), WPAN (for instance, Bluetooth® and ZigBeeR), WMAN (for instance, WiMax®), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 12 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAS) 811, low noise amplifiers (LNAs) 812, filters 813, switches 814, and signal splitting/combining circuitry 815. However, other implementations are possible.

For example, the front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 12, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 12, the power management system 805 receives a battery voltage from the battery 808. The battery 808 can be any suitable battery for use in the mobile device 800, including, for example, a lithium-ion battery.

FIG. 13 is a schematic diagram of a power amplifier system 860 according to one embodiment. The illustrated power amplifier system 860 includes a baseband processor 841, a transmitter/observation receiver 842, a power amplifier (PA) 843, a directional coupler 844, front-end circuitry 845, an antenna 846, a PA bias control circuit 847, and a PA supply control circuit 848. The illustrated transmitter/observation receiver 842 includes an I/Q modulator 857, a mixer 858, and an analog-to-digital converter (ADC) 859. In certain implementations, the transmitter/observation receiver 842 is incorporated into a transceiver.

The baseband processor 841 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals can be provided to the I/Q modulator 857 in a digital format. The baseband processor 841 can be any suitable processor configured to process a baseband signal. For instance, the baseband processor 841 can include a digital signal processor, a microprocessor, a programmable core, or any combination thereof. Moreover, in some implementations, two or more baseband processors 841 can be included in the power amplifier system 860.

The I/Q modulator 857 can be configured to receive the I and Q signals from the baseband processor 841 and to process the I and Q signals to generate an RF signal. For example, the I/Q modulator 857 can include digital-to-analog converters (DACs) configured to convert the I and Q signals into an analog format, mixers for upconverting the I and Q signals to RF, and a signal combiner for combining the upconverted I and Q signals into an RF signal suitable for amplification by the power amplifier 843. In certain implementations, the I/Q modulator 857 can include one or more filters configured to filter frequency content of signals processed therein.

The power amplifier 843 can receive the RF signal from the I/Q modulator 857, and when enabled can provide an amplified RF signal to the antenna 846 via the front-end circuitry 845.

The front-end circuitry 845 can be implemented in a wide variety of ways. In one example, the front-end circuitry 845 includes one or more switches, filters, duplexers, multiplexers, and/or other components. In another example, the front-end circuitry 845 is omitted in favor of the power amplifier 843 providing the amplified RF signal directly to the antenna 846.

The directional coupler 844 senses an output signal of the power amplifier 823. Additionally, the sensed output signal from the directional coupler 844 is provided to the mixer 858, which multiplies the sensed output signal by a reference signal of a controlled frequency. The mixer 858 operates to generate a downshifted signal by downshifting the sensed output signal's frequency content. The downshifted signal can be provided to the ADC 859, which can convert the downshifted signal to a digital format suitable for processing by the baseband processor 841. Including a feedback path from the output of the power amplifier 843 to the baseband processor 841 can provide a number of advantages. For example, implementing the baseband processor 841 in this manner can aid in providing power control, compensating for transmitter impairments, and/or in performing digital pre-distortion (DPD). Although one example of a sensing path for a power amplifier is shown, other implementations are possible.

The PA supply control circuit 848 receives a power control signal from the baseband processor 841, and controls supply voltages of the power amplifier 843. In the illustrated configuration, the PA supply control circuit 848 generates a first supply voltage V_{CC1} for powering an input stage of the power amplifier 843 and a second supply voltage V_{CC2} for powering an output stage of the power amplifier 843. The PA supply control circuit 848 can control the voltage level of the first supply voltage V_{CC1} and/or the second supply voltage V_{CC2} to enhance the power amplifier system's PAE.

The PA supply control circuit 848 can employ various power management techniques to change the voltage level of one or more of the supply voltages over time to improve the power amplifier's power added efficiency (PAE), thereby reducing power dissipation.

One technique for improving efficiency of a power amplifier is average power tracking (APT), in which a DC-to-DC converter is used to generate a supply voltage for a power amplifier based on the power amplifier's average output power. Another technique for improving efficiency of a power amplifier is envelope tracking (ET), in which a supply voltage of the power amplifier is controlled in relation to the envelope of the RF signal. Thus, when a voltage level of the envelope of the RF signal increases the voltage level of the power amplifier's supply voltage can be increased. Likewise, when the voltage level of the envelope of the RF signal decreases the voltage level of the power amplifier's supply voltage can be decreased to reduce power consumption.

In certain configurations, the PA supply control circuit 848 is a multi-mode supply control circuit that can operate in multiple supply control modes including an APT mode and an ET mode. For example, the power control signal from the baseband processor 841 can instruct the PA supply control circuit 848 to operate in a particular supply control mode.

As shown in FIG. 13, the PA bias control circuit 847 receives a bias control signal from the baseband processor 841, and generates bias control signals for the power amplifier 843. In the illustrated configuration, the bias control circuit 847 generates bias control signals for both an input stage of the power amplifier 843 and an output stage of the power amplifier 843. However, other implementations are possible.

### Applications

Some of the embodiments described above have provided examples in connection with mobile devices. However, the principles and advantages of the embodiments can be used for any other systems or apparatus that have needs for power amplifier systems. Examples of such RF communication systems include, but are not limited to, mobile phones, tablets, base stations, network access points, customer-premises equipment (CPE), laptops, and wearable electronics.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A mobile device comprising:
a transceiver configured to generate a radio frequency input signal; and
a front-end system including a power amplifier that includes a first amplification device configured to amplify a first signal component of a radio frequency input signal, a second amplification device configured to amplify a second signal component of the radio frequency input signal, a shared bias circuit having a first output configured to generate a first bias signal and a second output configured to generate a second bias signal, a first coupling impedance connected between the first output of the shared bias circuit and an input of the first amplification device, and a second coupling impedance connected between the second output of the shared bias circuit and an input of the second amplification device, the first coupling impedance configured to provide the first bias signal to the input of the first amplification device and to couple the first signal component into the first output, and the second coupling impedance configured to provide the second bias signal to the input of the second amplification device and to couple the second signal component into the second output.

2. The mobile device of claim 1 wherein the power amplifier further includes an input terminal configured to receive the radio frequency input signal.

3. The mobile device of claim 2 wherein the power amplifier further includes an input balun having a primary winding connected to the input terminal, and a secondary winding connect between the input of the first amplification device and the input of the second amplification device.

4. The mobile device of claim 3 wherein the power amplifier further includes a first capacitor connected between a first end of the secondary winding of the input balun and the input of the first amplification device, and a second capacitor connected between a second end of the secondary winding of the input balun and the input of the second amplification device.

5. The mobile device of claim 1 wherein the shared bias circuit generates the first bias signal and the second bias signal based on a common reference signal.

6. The mobile device of claim 1 wherein the first coupling impedance includes a first resistor and a first capacitor connected in parallel between the first output of the shared bias circuit and the input of the first amplification device, and the second coupling impedance includes a second resistor and a second capacitor connected in parallel between the second output of the shared bias circuit and the input of the second amplification device.

7. The mobile device of claim 1 wherein the shared bias circuit includes a first emitter follower bipolar transistor having an emitter connected to the first output of the shared bias circuit, and a second emitter follower bipolar transistor having an emitter connected to the second output of the shared bias circuit.

8. The mobile device of claim 7 wherein a base of the first emitter follower bipolar transistor and a base of the second emitter follower bipolar transistor receive a common reference signal.

9. The mobile device of claim 1 wherein the first amplification device includes a first bipolar transistor having a base corresponding to the input of the first amplification device, and the second amplification device includes a second bipolar transistor having a base corresponding to the input of the second amplification device.

10. The mobile device of claim 1 wherein the front end system includes a Doherty power amplifier system including the power amplifier.

11. The mobile device of claim 10 wherein the power amplifier is one of a peaking amplifier or a carrier amplifier of the Doherty power amplifier system.

12. A power amplifier comprising:
a first amplification device configured to amplify a first signal component of a radio frequency input signal;
a second amplification device configured to amplify a second signal component of the radio frequency input signal;
a shared bias circuit having a first output configured to generate a first bias signal and a second output configured to generate a second bias signal;
a first coupling impedance connected between the first output of the shared bias circuit and an input of the first amplification device, the first coupling impedance configured to provide the first bias signal to the input of the first amplification device and to couple the first signal component into the first output; and
a second coupling impedance connected between the second output of the shared bias circuit and an input of the second amplification device, the second coupling impedance configured to provide the second bias signal to the input of the second amplification device and to couple the second signal component into the second output.

13. The power amplifier of claim 12 further comprising an input terminal configured to receive the radio frequency input signal.

14. The power amplifier of claim 13 further comprising an input balun having a primary winding connected to the input terminal, and a secondary winding connect between the input of the first amplification device and the input of the second amplification device.

15. The power amplifier of claim 12 wherein the first coupling impedance includes a first resistor and a first capacitor connected in parallel between the first output of the shared bias circuit and the input of the first amplification device, and the second coupling impedance includes a second resistor and a second capacitor connected in parallel between the second output of the shared bias circuit and the input of the second amplification device.

16. The power amplifier of claim 12 wherein the shared bias circuit includes a first emitter follower bipolar transistor having an emitter connected to the first output of the shared bias circuit, and a second emitter follower bipolar transistor having an emitter connected to the second output of the shared bias circuit.

17. The power amplifier of claim 16 wherein a base of the first emitter follower bipolar transistor and a base of the second emitter follower bipolar transistor receive a common reference signal.

18. A method of radio frequency signal amplification in a mobile device, the method comprising:
amplifying a first signal component of a radio frequency input signal using a first amplification device of a power amplifier;
amplifying a second signal component of the radio frequency input signal using a second amplification device of the power amplifier;
generating a first bias signal at a first output of a shared bias circuit and a second bias signal at a second output of the shared bias circuit;
using a first coupling impedance to provide the first bias signal to the input of the first amplification device and to couple the first signal component into the first output; and
using a second coupling impedance to provide the second bias signal to the input of the second amplification device and to couple the second signal component into the second output.

19. The method of claim 18 wherein the shared bias circuit includes a first emitter follower bipolar transistor having an emitter connected to the first output of the shared bias circuit, and a second emitter follower bipolar transistor having an emitter connected to the second output of the shared bias circuit.

20. The method of claim 19 wherein a base of the first emitter follower bipolar transistor and a base of the second emitter follower bipolar transistor receive a common reference signal.

21.-50. (canceled)
